(19) United States
(12) Patent Application Publication
(10) Pub. No.: US 2025/0054889 A1
(43) Pub. Date: Feb. 13, 2025

(54) SEMICONDUCTOR PACKAGE

(71) Applicant: Samsung Electronics Co., Ltd., Suwon-si (KR)

(72) Inventor: Jinhee HONG, Suwon-si (KR)

(73) Assignee: Samsung Electronics Co., Ltd., Suwon-si (KR)

(21) Appl. No.: 18/734,002

(22) Filed: Jun. 5, 2024

(30) Foreign Application Priority Data
Aug. 9, 2023 (KR) 10-2023-0104215

(51) Int. Cl. H01L 23/00; H01L 25/065

(52) U.S. Cl. CPC H01L 24/08; H01L 24/06; H01L 24/48; H01L 25/0657; H01L 2224/06179; H01L 2224/08145; H01L 2224/08225; H01L 2224/48145; H01L 2224/48227; H01L 2225/06506; H01L 2225/0651; H01L 2225/06562; H01L 2924/1815

(57) ABSTRACT

A semiconductor package includes a package substrate having a plurality of substrate pads, a first semiconductor chip stacked on the package substrate and having a plurality of first chip pads and first option pads along a first horizontal direction, a plurality of first sub-chip pads along a second horizontal direction, and a plurality of first wirings electrically connecting the first chip pads and the first sub-chip pads, a second semiconductor chip stacked on the first semiconductor chip to cover the first sub-chip pads, and having a plurality of second chip pads and second option pads along the first horizontal direction, a plurality of second sub-chip pads along the second horizontal direction, and a plurality of second wirings electrically connecting the second chip pads and the second sub-chip pads, and a plurality of connection lines electrically connecting the package substrate and the first and second semiconductor chips.

### PRIORITY STATEMENT

This application claims priority under 35 U.S.C. § 119 to Korean Patent Application No. 10-2023-0104215, filed on Aug. 9, 2023 in the Korean Intellectual Property Office (KIPO), the contents of which are herein incorporated by reference in their entirety.

### BACKGROUND

### 1. Field

Example embodiments relate to semiconductor packages. More particularly, example embodiments relate to semiconductor packages including a plurality of semiconductor chips that are stacked on a package substrate.

### 2. Description of the Related Art

In a process of stacking a plurality of semiconductor chips on a package substrate, the package substrate and the plurality of semiconductor chips may be electrically connected to each other by a wire bonding process. In order to expose chip pads for wire bonding, the plurality of semiconductor chips may be stacked in a stepped shape to be tilted diagonally. When the plurality of semiconductor chips are stacked to be inclined diagonally, an overhang portion of the semiconductor chip may easily bend. When the chip pads of the semiconductor chip and substrate pads of the package substrate are electrically connected through conductive wires, there is a problem that the height of a semiconductor package increases.

### SUMMARY

Some example embodiments provide semiconductor packages having a structure that reduces an overhang portion to increases stability and reduces the number of conductive wires to reduce a height of the package.

According to an example embodiment, a semiconductor package includes a package substrate having a plurality of substrate pads, a first semiconductor chip stacked on the package substrate, the first semiconductor chip including a plurality of first chip pads, a plurality of first option pads, and a plurality of first wirings, the first chip pads and the first option pads along a first horizontal direction, the first sub-chip pads along a second horizontal direction perpendicular to the first direction, the first wirings electrically connecting the first chip pads and the first sub-chip pads to each other, a second semiconductor chip stacked on the first semiconductor chip to cover the first sub-chip pads, the second semiconductor chip including a plurality of second chip pads, a plurality of second option pads, and a plurality of second wirings, the second chip pads and the second option pads along the first horizontal direction, the second sub-chip pads along the second horizontal direction, the second wirings electrically connecting the second chip pads and the second sub-chip pads to each other, and a plurality of connection lines electrically connecting the package substrate and the first and second semiconductor chips.

According to an example embodiment, a semiconductor package includes a package substrate having a plurality of substrate pads, a first semiconductor chip stacked on the package substrate, the first semiconductor chip including a plurality of first chip pads, a plurality of first sub-chip pads, and a plurality of first wirings, the first chip pads along a first horizontal direction, the first sub-chip pads along a second horizontal direction perpendicular to the first horizontal direction, the first wirings electrically connecting first chip pads and the first sub-chip pads to each other, a second semiconductor chip stacked on the first semiconductor chip to cover the first sub-chip pads, the second semiconductor chip including a plurality of second chip pads, a plurality of second sub-chip pads, and a plurality of second wirings, the second chip pads along the first horizontal direction, the second sub-chip pads along the second horizontal direction, the second wirings electrically connecting the second chip pads and the second sub-chip pads to each other, and a plurality of connection lines electrically connecting the first and second chip pads and the second sub-chip pads to the substrate pads and configured to transmit a power signal or a ground signal.

According to an example embodiment, a semiconductor package includes a package substrate having a plurality of substrate pads, a first semi-package having first and second semiconductor chips sequentially stacked on the package substrate, a second semi-package having third and fourth semiconductor chips sequentially stacked on the first semi-package, and a plurality of connection lines electrically connecting the first and second semi-packages to the package substrate and configured to transmit a power signal or a ground signal. The first semiconductor chip includes a plurality of first chip pads along a first horizontal direction, a plurality of first sub-chip pads along a second horizontal direction perpendicular to the first horizontal direction, and a plurality of first wirings electrically connecting the first chip pads and the first sub-chip pads to each other. The second semiconductor chip includes a plurality of second chip pads along the first horizontal direction, a plurality of second sub-chip pads along the second horizontal direction, and a plurality of second wirings electrically connecting the second chip pads and the second sub-chip pads to each other. The second semiconductor chip is stacked on the first semiconductor chip to cover the first sub-chip pads and expose the first chip pads. The third semiconductor chip includes a plurality of third chip pads along the first horizontal direction, a plurality of third sub-chip pads along the second horizontal direction, and a plurality of third wirings electrically connecting the third chip pads and the third sub-chip pads to each other. The third semiconductor chip is stacked on the second semiconductor chip to expose the second chip pads and the second sub-chip pads. The fourth semiconductor chip includes a plurality of fourth chip pads along the first horizontal direction, a plurality of fourth sub-chip pads along the second horizontal direction, and a plurality of fourth wirings electrically connecting the fourth chip pads and the sub-chip pads to each other. The fourth semiconductor chip is stacked on the third semiconductor chip to cover the third sub-chip pads and expose the third chip pads.

The first and second semiconductor chips may be sequentially stacked on the package substrate. Because the second semiconductor chip is stacked to cover the first sub-chip pads of the first semiconductor chip, an overlap area between the first and second semiconductor chips when viewed in plan view may increase. Because the overlap area between the first and second semiconductor chips increases, an overhang portion may decrease, thereby reducing a bending phenomenon occurring in the second semiconductor chip.

Because the first sub-chip pads of the first semiconductor chip are covered by the second semiconductor chip, the first sub-chip pads may be electrically connected to the first chip pads through the first wirings. Because the first sub-chip pads are electrically connected to the first chip pads through the first wirings, the first sub-chip pads may reinforce the power signal or the ground signal transmitted through the first chip pads.

In addition, because the plurality of connection lines may not need to electrically connect the first sub-chip pads to the plurality of upper substrate pads, a first height of a molding member for covering the plurality of connection lines on the package substrate may be reduced. Because the first height of the molding member is reduced, the overall height of the semiconductor package may be reduced.

### BRIEF DESCRIPTION OF THE DRAWINGS

Example embodiments will be more clearly understood from the following detailed description taken in conjunction with the accompanying drawings. FIGS. 1 to 6 represent non-limiting, example embodiments as described herein.

FIG. 1 is a perspective view illustrating a semiconductor package in accordance with an example embodiment.

FIG. 2 is a plan view illustrating a package substrate on which first semiconductor chips are stacked in accordance with an example embodiment.

FIG. 3 is a plan view illustrating the package substrate on which the first semiconductor chip and a second semiconductor chips are stacked in accordance with an example embodiment.

FIG. 4 is a cross-sectional view taken along the line A-A′, the ling B-B′ and the line C-C′ in FIG. 3.

FIG. 5 is a perspective view illustrating a semiconductor package in accordance with an example embodiment.

FIG. 6 is a plan view illustrating a package substrate on which first to fourth semiconductor chips are stacked in accordance with an example embodiment.

### DETAILED DESCRIPTION

Hereinafter, some example embodiments will be explained in detail with reference to the accompanying drawings.

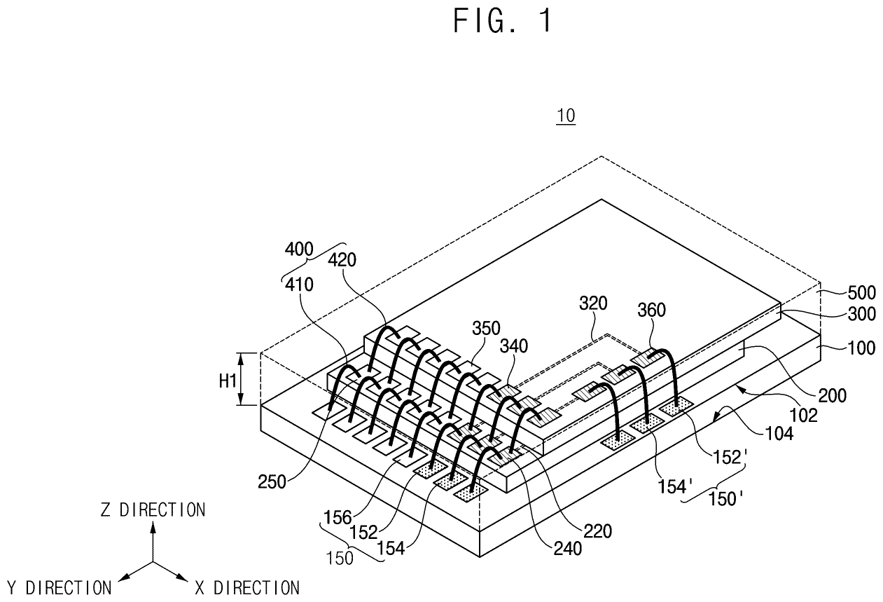

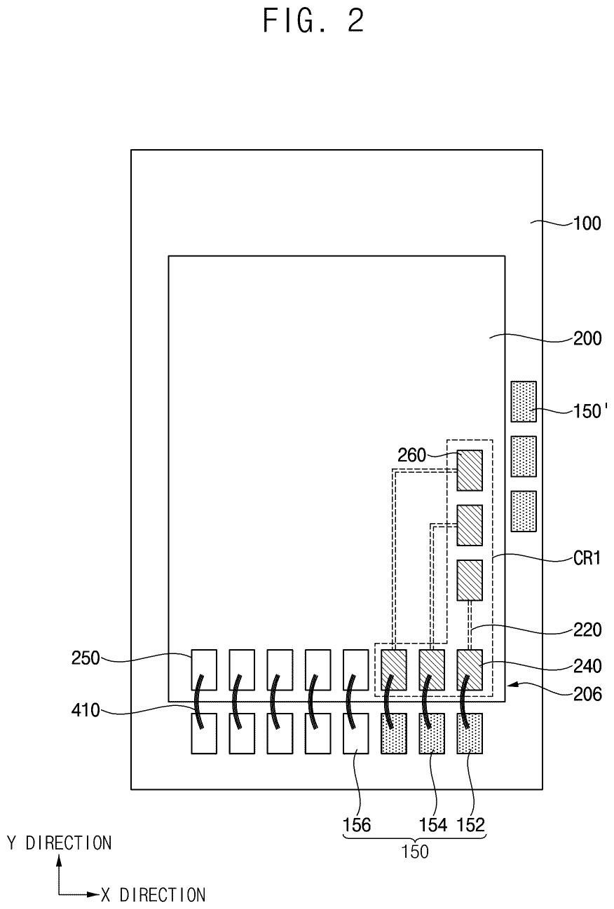

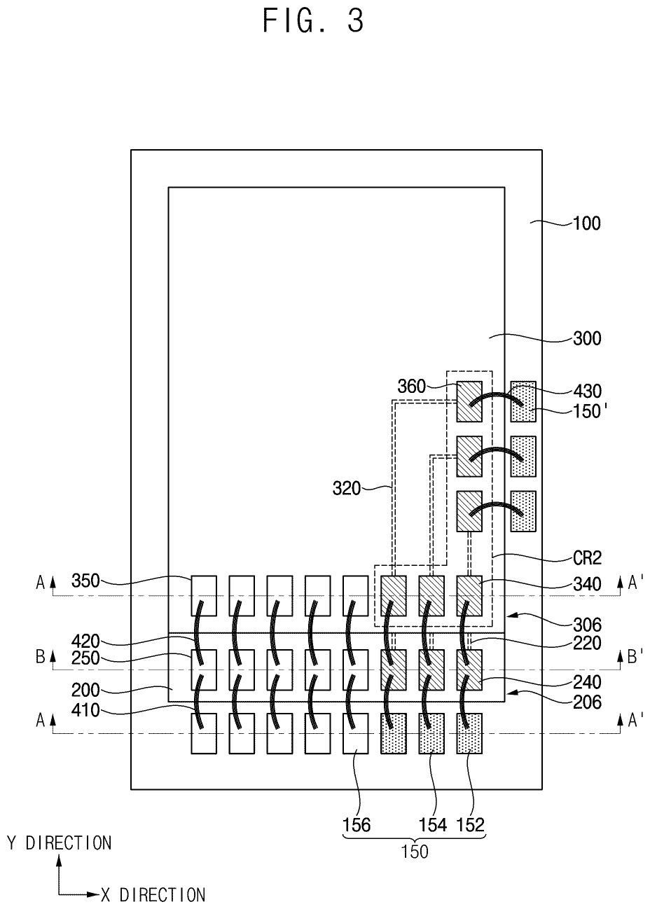

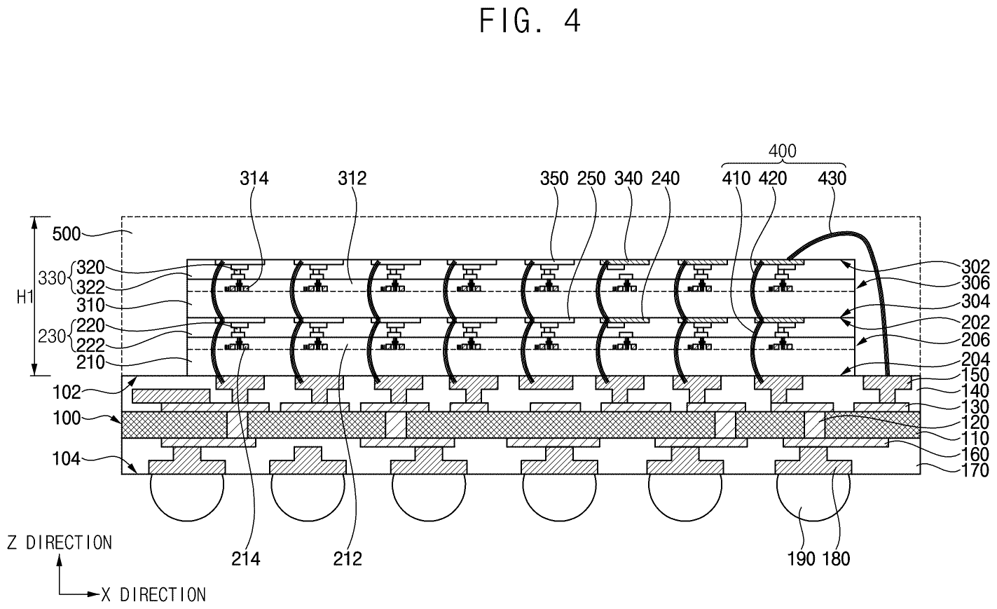

FIG. 1 is a perspective view illustrating a semiconductor package in accordance with an example embodiment. FIG. 2 is a plan view illustrating a package substrate on which first semiconductor chips are stacked in accordance with an example embodiment. FIG. 3 is a plan view illustrating the package substrate on which the first semiconductor chip and a second semiconductor chips are stacked in accordance with an example embodiment. FIG. 4 is a cross-sectional view taken along the line A-A′, the ling B-B′ and the line C-C′ in FIG. 3.

Referring to FIGS. 1 to 4, a semiconductor package 10 may include a package substrate 100, first and second semiconductor chips 200 and 300 sequentially stacked on the package substrate 100, and a plurality of connection lines 400 configured to electrically connect the package substrate 100 and the first and second semiconductor chips 200 and 300. The first and second semiconductor chips 200 and 300 may be the same type of semiconductor devices.

The first and second semiconductor chips 200 and 300 may be stacked on the semiconductor package 10 in an inclined stepped shape. In this specification, a direction (Y direction) in which the inclined staircase shape extends may be referred to as a second horizontal direction, and a horizontal direction (X direction) perpendicular to the second horizontal direction may be referred to as a first horizontal direction. A direction (Z direction) perpendicular to the first horizontal direction and the second horizontal direction will be referred to as a vertical direction.

In some example embodiments, the package substrate 100 may have a first surface 102 and a second surface 104 opposite to the first surface 102. The first and second semiconductor chips 200 and 300 may be sequentially stacked on the first surface 102 of the package substrate 100, and the package substrate 100 may be electrically connected to the first and second semiconductor chips 200 and 300. For example, the package substrate 100 may include a printed circuit board (PCB), a flexible substrate, a tape substrate, etc. The printed circuit board may be a multilayer circuit board having vias and various circuits therein.

The package substrate 100 may include a core layer 110, a conductive through via 120, an upper conductive pattern 130, an upper insulating layer 140, a plurality of upper substrate pads 150, a lower conductive pattern 160, a lower insulating layer 170, a plurality of lower substrate pads 180, and a plurality of external connection bumps 190.

The core layer 110 may include a non-conductive material layer. The core layer 110 may include a reinforcing polymer or the like. The core layer 110 may serve as a boundary layer that divides the package substrate 100 into an upper portion and a lower portion.

The conductive through via 120 may penetrate (e.g., extend into) the core layer 110, and may electrically connect the upper conductive pattern 130 and the lower conductive pattern 160. When the first and second semiconductor chips 200 and 300 are disposed on the first surface 102 of the package substrate 100, the conductive through via 120 may electrically connect the first and second semiconductor chips 200 and 300 and other semiconductor devices that are provided on the second surface 104 of the package substrate 100. That is, the conductive through via 120 may electrically connect the first and second semiconductor chips 200 and 300 on the first surface 102 of the package substrate 100 to other semiconductor devices that are provided on the second surface 104 of the package substrate 100.

The upper insulating layer 140 and the lower insulating layer 170 may include polymer or a dielectric layer. The upper insulating layer 140 and lower insulating layer 170 may be formed by a vapor deposition process, a spin coating process, or the like.

The upper conductive pattern 130 may be provided in the upper insulating layer 140. The upper conductive pattern 130 may be electrically connected to the first and second semiconductor chips 200 and 300. The upper conductive patterns 130 may include power wirings or ground wirings as a power net for supplying power to electronic components mounted on the package substrate 100. A power signal or a ground signal may be transmitted through the upper conductive pattern 130. The upper conductive pattern 130 may extend in a longitudinal direction of the core layer 110 within the upper insulating layer 140. A lower surface of the upper conductive pattern 130 may be in contact with the core layer 110.

The upper substrate pads 150 may be exposed from the first surface 102 of the package substrate 100. The upper substrate pads 150 may be provided in the upper insulating layer 140. The upper substrate pads 150 may be electrically connected to the upper conductive patterns 130.

The upper substrate pads 150 may include at least one power pad 152 electrically connected to the power wiring, and at least one ground pad 154 connected to the ground wiring. The upper substrate pads 150 may further include a plurality of signal pads 156 that are configured to transmit data signals to the electronic components.

Although only some upper substrate pads are illustrated in the drawings, it will be understood that the number and arrangement of the upper substrate pads in the drawings are merely some examples, and are not limited thereto.

The lower conductive pattern 160 may be provided in the lower insulating layer 170. The lower conductive pattern 160 may be electrically connected to the first and second semiconductor chips 200 and 300. The power signal or the ground signal may be transmitted through the lower conductive pattern 160. The data signal may be transmitted through the lower conductive pattern 160. The lower conductive pattern 160 may extend in the longitudinal direction of the core layer 110 within the lower insulating layer 170. An upper surface of the lower conductive pattern 160 may be in contact with the core layer 110.

The lower substrate pads 180 may be exposed from the second surface 104 of the package substrate 100. The lower substrate pads 180 may be provided in the lower insulating layer 170. The lower substrate pads 180 may be electrically connected to the lower conductive patterns 160. The external connection bumps 190 may be provided on the lower substrate pads 180 to electrical connect to external devices. For example, the external connection bump 190 may include a solder ball.

The upper and lower substrate pads 150 and 180 and the upper and lower conductive patterns 130 and 160 may include aluminum (Al), copper (Cu), tin (Sn), nickel (Ni), gold (Au), platinum (Pt), or alloys thereof. The upper and lower substrate pads 150 and 180 and the upper and lower conductive patterns 130 and 160 may be formed by a plating process, an electroless plating process, a vapor deposition process, etc.

In some example embodiments, the first semiconductor chip 200 may include a first substrate 210, a first activation layer 212 provided on a first surface of the first substrate 210, and a first wiring layer 230 having first wirings 220 provided on the first activation layer 212 and electrically connected to a plurality of first circuit patterns 214. The first semiconductor chip 200 may have a first upper surface 202 and a first lower surface 204 opposite to the first upper surface 202.

In some example embodiments, the first activation layer 212 may include a first circuit layer therein. The first circuit layer may include the plurality of first circuit patterns 214 therein. The first circuit patterns 214 may include transistors, diodes, etc. The first circuit patterns 214 may be formed on the first surface of the first substrate 210 through a wafer process called front-end-of-line (FEOL).

The type of the first semiconductor chip 200 may be determined based on the first circuit patterns of the first activation layer 212. For example, the first activation layer 212 may include an application processor (AP). The first activation layer 212 may include SRAM (Static Random Access Memory), DRAM (dynamic random access memory), NAND Flash Memory, and Silicon Carbide Circuit (SiC Circuit), etc.

The first wiring layer 230 may be provided on the first upper surface 202 of the first semiconductor chip 200. The first wiring layer 230 may be formed on the first surface of the first substrate 210 by a wiring process called back-end-of-line (BEOL). The first wiring layer 230 may include a first insulating layer 222 and the first wirings 220 provided in the first insulating layer 222. For example, the first insulating layer 222 may include a polymer, a dielectric layer, etc. The first insulating layer 222 may include polyimide (PI), lead oxide (PbO), polyhydroxystyrene (PHS), or novolac (NOVOLAC). The first insulating layer 222 may be formed by a vapor deposition process, a spin coating process, etc.

The first wirings 220 may be formed by forming a seed layer on a portion of the first insulating layer 222 and in an opening in the first insulating layer 222, patterning the seed layer and then performing an electrolytic plating process. Accordingly, at least a portion of the first wiring 220 may directly contact the wiring of another layer through the opening. The first wirings 220 may be electrically connected to the first circuit patterns 214. For example, the first wiring 220 may include aluminum (Al), copper (Cu), tin (Sn), nickel (Ni), gold (Au), platinum (Pt), or alloys thereof.

In some example embodiments, the first semiconductor chip 200 may include a plurality of first chip pads 240 and first option pads 250 that are arranged to be spaced apart from each other in the first horizontal direction (X direction), and a plurality of first sub-chip pads 260 that are arranged to be spaced apart from each other in the second horizontal direction (Y direction). The first chip pads 240, the first option pads 250, and the first sub-chip pads 260 may be exposed from the first upper surface 202 of the first semiconductor chip 200.

The first chip pads 240 may be arranged to be spaced apart from the power pads 152 or the ground pads 154 in the second horizontal direction (Y direction). The first chip pads 240 may be electrically connected to the power pads 152 or the ground pads 154 through the connection lines 400. The first chip pads 240 may receive the power signal from the power pads 152 or the ground signal from the ground pads 154.

The first option pads 250 may be arranged to be spaced apart from the first chip pads 240 in the first horizontal direction (X direction). The first option pads 250 may be arranged to be spaced apart from the upper substrate pads 150 in the second horizontal direction (Y direction). The first option pads 250 may be electrically connected to the upper substrate pads 150 through the connection lines 400. The first option pads 250 may receive the data signal from the upper substrate pads 150.

The plurality of first sub-chip pads 260 may be arranged to be spaced apart from the first chip pads 240 in the second horizontal direction (Y direction). For example, the plurality of first sub-chip pads 260 may be arranged to be sequentially spaced apart from any one of the first chip pads 240 in the second horizontal direction (Y direction). In some example embodiments, the plurality of first sub-chip pads 260 may be arranged to be spaced apart from the first option pads 250 in the second horizontal direction (Y direction).

The plurality of first sub-chip pads 260 may be arranged along a first side portion 206 of the first semiconductor chip 200. The plurality of first sub-chip pads 260 may be arranged adjacent to the first side portion 206. For example, the first side portion 206 may have a side surface extending in a longitudinal direction (Y direction) of the first semiconductor chip 200.

The plurality of first sub-chip pads 260 may be electrically connected to the plurality of first chip pads 240 through the first wirings 220, respectively. The plurality of first sub-chip pads 260 may receive the power signal or the ground signal from the first chip pads 240.

Because the plurality of first sub-chip pads 260 are electrically connected to the plurality of first chip pads 240 through the first wirings 220, the plurality of first sub-chip pads 260 may reduce electrical loads that are applied to the plurality of first chip pads 240 from the power signal or the ground signal. The first sub-chip pads 260 may reinforce the power signal or the ground signal through the first wirings 220.

The plurality of first sub-chip pads 260 may be provided on a first corner region CR1 of the first semiconductor chip 200 together with the first chip pads 240. The first corner region CR1 may be provided on any one of four corners of the first semiconductor chip 200. The first corner region CR1 may be provided on a region adjacent to the upper substrate pads 150′ among the four corner regions. For example, the first corner region CR1 may have an “L” shape.

The plurality of first chip pads 240 and first option pads 250 may be arranged to be spaced apart from each other in the first horizontal direction (X direction). For example, the number of the first chip pads 240 may range from 4 to 8. The number of the first sub-chip pads 260 may range from 4 to 8.

In some example embodiments, the second semiconductor chip 300 may include a second substrate 310, a second activation layer 312 provided on a first surface of the second substrate 310, and a second wiring layer 330 having second wirings 320 provided on the second activation layer 312 and electrically connected to a plurality of second circuit patterns 314. The second semiconductor chip 300 may be the same type of semiconductor device as the first semiconductor chip 200. The second semiconductor chip 300 may have a second upper surface 302 and a second lower surface 304 opposite to the second upper surface 302.

The second semiconductor chip 300 may be stacked on the first semiconductor chip 200 in a stepped shape. The second semiconductor chip 300 may be stacked in the stepped shape such that the second semiconductor chip 300 exposes the first chip pads 240 and the first option pads 250 of the first semiconductor chip 200.

The second semiconductor chip 300 may be provided to cover the first sub-chip pads 260 of the first semiconductor chip 200. Because the second semiconductor chip 300 covers the first sub-chip pads 260, an overlap area between the first and second semiconductor chips 200 and 300 may increase. As the overlap area between the first and second semiconductor chips 200 and 300 increases, an overhang region of the second semiconductor chip 300 protruding from the first semiconductor chip 200 may be reduced. Due to the reduction of the overhang portion, deflection from occurring in the overhang portion may be reduced or prevented.

Because the first sub-chip pads 260 are electrically connected to the first chip pads 240 through the first wirings 220, even though the second semiconductor chip 300 covers the first sub-chip pads 260, the first sub-chip pads 260 may reinforce the power signal or the ground signal.

In some example embodiments, the second activation layer 312 may include a second circuit layer therein. The second circuit layer may include the plurality of second circuit patterns 314 therein. The second wiring layer 330 may be provided in the second upper surface 302 of the second semiconductor chip 300. The second wiring layer 330 may include a second insulating layer 322 and the second wirings 320 provided in the second insulating layer 322.

In some example embodiments, the second semiconductor chip 300 may include a plurality of second chip pads 340 and second option pads 350 that are arranged to be spaced apart from each other in the first horizontal direction (X direction), and a plurality of second sub-chip pads 360 that are arranged to be spaced apart from each other in the second horizontal direction (Y direction). The second chip pads 340, the second option pads 350, and the second sub-chip pads 360 may be exposed from the second upper surface 302 of the second semiconductor chip 300.

The second chip pads 340 may be arranged to be spaced apart from the first chip pads 240 of the first semiconductor chip 200 in the second horizontal direction (Y direction). The second chip pads 340 may be electrically connected to the first chip pads 240 through the connection lines 400. The second chip pads 340 may receive the power signal or the ground signal from the first chip pads 240.

The second option pads 350 may be arranged to be spaced apart from the second chip pads 340 in the first horizontal direction (X direction). The second option pads 350 may be arranged to be spaced apart from the first option pads 250 of the first semiconductor chip 200 in the second horizontal direction (Y direction). The second option pads 350 may be electrically connected to the first option pads 250 through the connection lines 400. The second option pads 350 may receive the data signal from the first option pads 250.

The plurality of second sub-chip pads 360 may be arranged to be spaced apart from the second chip pads 340 in the second horizontal direction (Y direction). For example, the plurality of second sub-chip pads 360 may be arranged to be sequentially spaced apart from any one of the second chip pads 340 in the second horizontal direction (Y direction). In some example embodiments, the plurality of second sub-chip pads 360 may be arranged to be spaced apart from the second option pads 350 in the second horizontal direction (Y direction).

The plurality of second sub-chip pads 360 may be arranged along a second side portion 306 of the second semiconductor chip 300. The plurality of second sub-chip pads 360 may be arranged adjacent to the second side portion 306. For example, the second side portion 306 may have a side surface extending in a longitudinal direction (Y direction) of the second semiconductor chip 300.

For example, the second side portion 306 of the second semiconductor chip 300 may be provided on the same plane as the first side portion 206 of the first semiconductor chip 200. Because the first side portion 206 and the second side portion 306 are provided on the same plane, the overlap area between the first and second semiconductor chips 200 and 300 may increase. As the overlap area between the first and second semiconductor chips 200 and 300 increases, structural stability between the first and second semiconductor chips 200 and 300 may increase.

The plurality of second sub-chip pads 360 may be electrically connected to the plurality of second chip pads 340 through the second wirings 320, respectively. The plurality of second sub-chip pads 360 may receive the power signal or the ground signal from the second chip pads 340.

Because the plurality of second sub-chip pads 360 are electrically connected to the plurality of second chip pads 340 through the second wirings 320, the plurality of second sub-chip pads 360 may reduce electrical loads that are applied to the plurality of second chip pads 340 from the power signal or the ground signal. The second sub-chip pads 360 may reinforce the power signal or the ground signal through the second wirings 320.

The plurality of second sub-chip pads 360 may be electrically connected to the upper substrate pads 150′ of the package substrate 100 through the connection lines 400, respectively. The plurality of second sub-chip pads 360 may transmit the power signal or the ground signal to the upper substrate pads 150′.

Because the plurality of second sub-chip pads 360 are electrically connected to the plurality of upper substrate pads 150′ through the connection lines 400, the plurality of second sub-chip pads 360 may reduce electrical loads that are applied to the plurality of second chip pads 340 from the power signal or the ground signal. The second sub-chip pads 360 may reinforce the power signal or the ground signal through the second wirings 320 and the connection lines 400.

The plurality of second sub-chip pads 360 may be provided on a second corner region CR2 of the second semiconductor chip 300 together with the second chip pads 340. The second corner region CR2 may be provided on any one of four corners of the second semiconductor chip 300. The second corner region CR2 may be a region corresponding to the first corner region CR1 of the first semiconductor chip 200. The second corner region CR2 may be provided on a region adjacent to the first chip pads 240 among the four corner regions. For example, the second corner region CR2 may have an “L” shape.

In some example embodiments, the plurality of connection lines 400 may electrically connect the package substrate 100 and the first and second semiconductor chips 200 and 300. The plurality of connection lines 400 may include first to third conductive wires 410, 420, and 430. The first and second conductive wires 410 and 420 may extend in the second horizontal direction (Y direction), respectively. The third conductive wires 430 may extend in the first horizontal direction (X direction), respectively.

The first conductive wires 410 may transmit the power signal, the ground signal, or the data signal between the package substrate 100 and the first semiconductor chip 200. The first conductive wires 410 may electrically connect the upper substrate pads 150 to the first chip pads 240 and the first option pads 250, respectively.

The first conductive wires 410 may transmit the power signal from the power pads 152 to the first chip pads 240. The first conductive wires 410 may transmit the ground signal from the ground pads 154 to the first chip pads 240. The first conductive wires 410 may transmit the data signal from the upper substrate pads 150 to the first option pads 250.

The second conductive wires 420 may transmit the power signal, the ground signal, or the data signal between the first and second semiconductor chips 200 and 300. The second conductive wires 420 may electrically connect the first chip pads 240 and the second chip pads 340 to each other. The second conductive wires 420 may electrically connect the first option pads 250 and the second option pads 350 to each other.

The second conductive wires 420 may transmit the power signal or the ground signal from the first chip pads 240 to the second chip pads 340. The second conductive wires 420 may transmit the data signal from the first option pads 250 to the second option pads 350.

The third conductive wires 430 may transmit the power signal or the ground signal between the package substrate 100 and the second semiconductor chip 300. The third conductive wires 430 may electrically connect the upper substrate pads 150′ and the second sub-chip pads 360 to each other. The third conductive wires 430 may transmit the power signal or the ground signal from the second sub-chip pads 360 to the upper substrate pads 150′.

For example, the first to third conductive wires 410, 420 and 430 may include copper (Cu), aluminum (Al), tungsten, nickel (Ni), molybdenum (Mo), gold (Au), silver (Ag), chromium (Cr), tin (Sn), titanium (Ti) or alloys thereof.

In some example embodiments, the semiconductor package 10 may further include a molding member 500 that covers the first and second semiconductor chips 200 and 300 on the package substrate 100.

The molding member 500 may be formed on the package substrate 100 to protect the first and second semiconductor chips 200 and 300 and the connection lines 400 from the outside. For example, the molding member 500 may include an epoxy mold compound (EMC).

The molding member 500 may have a first height H1 from the first surface 102 of the package substrate 100. Because the first sub-chip pads 260 of the first semiconductor chip 200 are electrically connected to the first chip pads 240 through the first wirings 220, the first sub-chip pads 260 may not be in direct contact with the connection lines 400. Because the number of the connection lines 400 for electrically connecting the first sub-chip pads 260 to the package substrate 100 is reduced, the first height H1 of the molding member 500 may be reduced. Because the first height H1 of the molding member 500 decreases, a thickness of the semiconductor package 10 may decrease.

As described above, the first and second semiconductor chips 200 and 300 may be sequentially stacked on the package substrate 100. Because the second semiconductor chip 300 is stacked to cover the first sub-chip pads 260 of the first semiconductor chip 200, the overlap area between the first and second semiconductor chips 200 and 300 when viewed in plan view may increase. Because the overlap area between the first and second semiconductor chips 200 and 300 increases, the overhang portion may decrease to thereby reducing the bending phenomenon occurring in the second semiconductor chip 300.

Because the first sub-chip pads 260 of the first semiconductor chip 200 are covered by the second semiconductor chip 300, the first sub-chip pads 260 may be electrically connected to the first chip pads 240 through the first wirings 220. Because the first sub-chip pads 260 are electrically connected to the first chip pads 240 through the first wirings 220, the first sub-chip pads 260 may reinforce the power signal or the ground signal transmitted through the first chip pads 240.

Because the plurality of connection lines 400 is not needed to electrically connect the first sub-chip pads 260 to the plurality of upper substrate pads 150, the first height H1 of the molding member 500 for covering the plurality of connection lines on the package substrate 100 may be reduced. Because the first height H1 of the molding member 500 is reduced, the overall height of the semiconductor package 10 may be reduced.

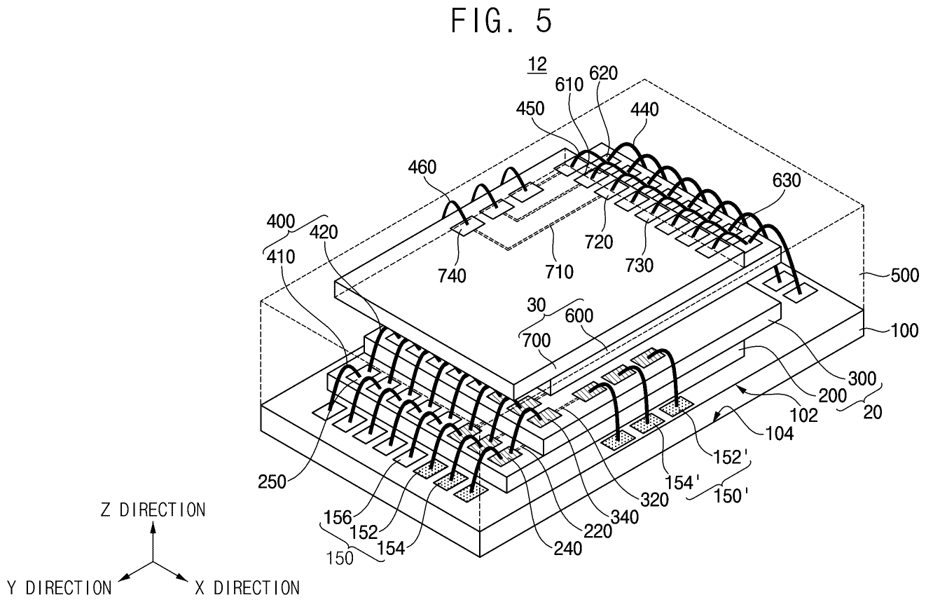

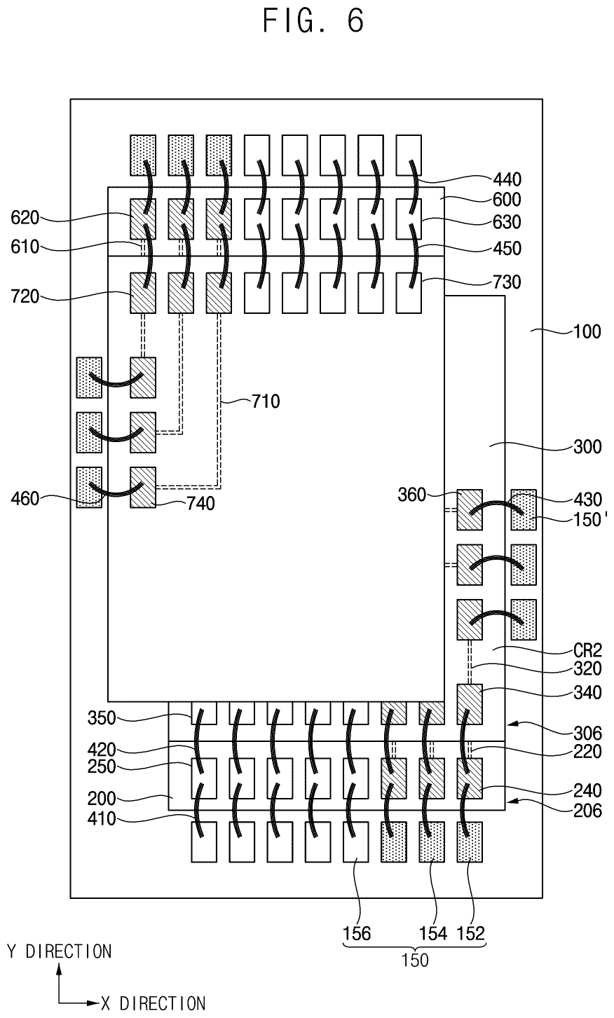

FIG. 5 is a perspective view illustrating a semiconductor package in accordance with an example embodiment. FIG. 6 is a plan view illustrating a package substrate on which first to fourth semiconductor chips are stacked in accordance with an example embodiment. The semiconductor package may be substantially the same as or similar to the semiconductor package described with reference to FIGS. 1 to 4 except for additional third and fourth semiconductor chips. Thus, same reference numerals may be used to the same or like elements and any further repetitive explanation concerning the above elements will be omitted.

Referring to FIGS. 5 and 6, a semiconductor package 12 may include a first semi-package 20 having first and second semiconductor chips 200 and 300, and a second semi-package 30 having third and fourth semiconductor chips 600 and 700. The first to fourth semiconductor chips 200, 300, 600, and 700 may be the same type of a semiconductor device.

The first semi-package 20 may be provided on a package substrate 100. The first and second semiconductor chips 200 and 300 may be sequentially stacked on the package substrate 100 to form the first semi-package 20. The second semi-package 30 may be provided on the first semi-package 20. The third and fourth semiconductor chips 600 and 700 may be sequentially stacked on the first semi-package 20 as the second semi-package 30.

In some example embodiments, a plurality of connection lines 400 may electrically connect the package substrate 100 and the first and second semi-packages 20 and 30. The plurality of connection lines 400 may include first to sixth conductive wires 410, 420, 430, 440, 450, and 460.

In some example embodiments, the third semiconductor chip 600 may include a plurality of third chip pads 620 and third option pads 630 arranged to be spaced apart from each other in a first horizontal direction (X direction), and a plurality of third sub-chip pads (not shown) arranged to be spaced apart from each other in a second horizontal direction (Y direction).

The third chip pads 620 may be electrically connected to power pads 152 or ground pads 154 through the fourth conductive wires 440. The third option pads 630 may be electrically connected to upper substrate pads 150 through the fourth conductive wires 440. The plurality of third sub-chip pads may be electrically connected to the plurality of third chip pads 620 through third wirings 610, respectively. The plurality of third sub-chip pads may receive a power signal or a ground signal from the third chip pads 620 through the third wirings 610.

The third semiconductor chip 600 may be stacked such that second chip pads 340, second option pads 350, and second sub-chip pads 360 of the second semiconductor chip 300 are exposed. The third semiconductor chip 600 may be stacked on the second semiconductor chip 300 to expose a second corner region CR2 of the second semiconductor chip 300.

Because the third semiconductor chip 600 exposes the second chip pads 340, the second option pads 350, and the second sub-chip pads 360, the second and third conductive wires 420, 430 may electrically connect the second chip pads 340, the second option pads 350, and the second sub-chip pads 360 to the package substrate 100 or the first semiconductor chip 200.

In some example embodiments, the fourth semiconductor chip 700 may be stacked on the third semiconductor chip 600 in a stepped shape. Because the fourth semiconductor chip 700 is stacked in the stepped shape, the fourth semiconductor chip 700 may expose the third chip pads 620 and the third option pads 630 of the third semiconductor chip 600.

The fourth semiconductor chip 700 may be provided to cover the third sub-chip pads of the third semiconductor chip 600. Because the fourth semiconductor chip 700 covers the third sub-chip pads, an overlap area between the third and fourth semiconductor chips 600 and 700 may increase. Because the overlap area between the third and fourth semiconductor chips 600 and 700 increases, an overhang portion of the fourth semiconductor chip 700 protruding from the third semiconductor chip 600 may be reduced.

The fourth semiconductor chip 700 may include a plurality of fourth chip pads 720 and fourth option pads 730 arranged to be spaced apart from each other in the first horizontal direction (X direction), and a plurality of fourth sub-chip pads 740 arranged to be spaced apart from each other in the second horizontal direction (Y direction).

The fourth chip pads 720 may be electrically connected to the third chip pads 620 through the fifth conductive wires 450. The fourth option pads 730 may be electrically connected to the third option pads 630 through the fifth conductive wires 450. The plurality of fourth sub-chip pads 740 may be electrically connected to the upper substrate pads 150 of the package substrate 100 through the sixth conductive wires 460, respectively. The plurality of fourth sub-chip pads 740 may receive the power signal or the ground signal from the fourth chip pads 720 through fourth wirings 710.

The foregoing is illustrative of some example embodiments and is not to be construed as limiting thereof. Although a few example embodiments have been described, those skilled in the art will readily appreciate that many modifications are possible in the disclosed example embodiments without materially departing from the novel teachings and advantages of the present inventive concepts. Accordingly, all such modifications are intended to be included within the scope of example embodiments as defined in the claims.

1. A semiconductor package, comprising:
a package substrate having a plurality of substrate pads;
a first semiconductor chip stacked on the package substrate, the first semiconductor chip including a plurality of first chip pads, a plurality of first option pads, a plurality of first sub-chip pads, and a plurality of first wirings, the first chip pads and the first option pads along a first horizontal direction, the first sub-chip pads along a second horizontal direction perpendicular to the first horizontal direction, the first wirings electrically connecting the first chip pads and the first sub-chip pads to each other;
a second semiconductor chip stacked on the first semiconductor chip to cover the first sub-chip pads, the second semiconductor chip including a plurality of second chip pads, a plurality of second option pads, a plurality of second sub-chip pads, and a plurality of second wirings, the first chip pads and the second option pads along the first horizontal direction, the second sub-chip pads along the second horizontal direction, the second wirings electrically connecting the second chip pads and the second sub-chip pads to each other; and
a plurality of connection lines electrically connecting the package substrate and the first and second semiconductor chips.

2. The semiconductor package of claim 1, wherein the plurality of connection lines include:
first conductive wires electrically connecting the plurality of substrate pads and the first chip pads; and
second conductive wires electrically connecting the first chip pads and the second chip pads.

3. The semiconductor package of claim 2, wherein the first chip pads and the second chip pads are configured to receive a power signal or a ground signal from the package substrate through the first and second conductive wires.

4. The semiconductor package of claim 3, wherein the first sub-chip pads are configured to receive the power signal or the ground signal from the first chip pads through the first wirings.

5. The semiconductor package of claim 2, wherein the first conductive wires electrically connect the plurality of substrate pads and the first option pads, respectively, and the second conductive wires electrically connect the first option pads and the second option pads, respectively.

6. The semiconductor package of claim 5, wherein the first option pads and the second option pads receive data signals from the package substrate through the first and second conductive wires.

7. The semiconductor package of claim 1, wherein the plurality of connection lines further include third conductive wires that electrically connect the plurality of substrate pads and the second sub-chip pads, respectively.

8. The semiconductor package of claim 7, wherein the second sub-chip pads are configured to transmit a power signal or a ground signal to the package substrate through the third conductive wires.

9. The semiconductor package of claim 1, wherein the second semiconductor chip is stacked on the first semiconductor chip in a stepped shape in the second horizontal direction.

10. The semiconductor package of claim 1, wherein the first chip pads are spaced apart from the second chip pads in the second horizontal direction, and the first option pads are spaced apart from the second option pads in the second horizontal direction.

11. The semiconductor package of claim 1, wherein the plurality of first sub-chip pads are along a first side portion of the first semiconductor chip,
the plurality of second sub-chip pads are along a second side portion of the second semiconductor chip, and
the first and second side portions are on a same plane.

12. The semiconductor package of claim 1, wherein the first chip pads and the first sub-chip pads are on a first corner region of the first semiconductor chip, and
the second chip pads and the second sub-chip pads are on a second corner region of the second semiconductor chip corresponding to the first corner region.

13. The semiconductor package of claim 1, wherein the first and second semiconductor chips are a same type of semiconductor device.

14. The semiconductor package of claim 1, further comprising:
a third semiconductor chip stacked on the second semiconductor chip to expose the second chip pads, the second option pads and the second sub-chip pads, the third semiconductor chip including a plurality of third chip pads, a plurality of third sub-chip pads, and a plurality of third wirings, the third chip pads along the first horizontal direction, the third sub-chip pads along the second horizontal direction, the third wirings electrically connecting the third chip pads and the third sub-chip pads to each other; and
a fourth semiconductor chip stacked on the third semiconductor chip to cover the third sub-chip pads, the fourth semiconductor chip including a plurality of fourth chip pads, a plurality of fourth sub-chip pads, and plurality of fourth wirings, the fourth chip pads along the first horizontal direction, the fourth sub-chip pads along the second horizontal direction, the fourth wirings electrically connecting the fourth chip pads and the fourth sub-chip pads to each other,
wherein the plurality of connection lines electrically connect the package substrate and the third and fourth semiconductor chips.

15. The semiconductor package of claim 14, wherein the plurality of connection lines further include:
fourth conductive wires electrically connecting the plurality of substrate pads and the third chip pads, respectively;
fifth conductive wires electrically connecting the third chip pads and the fourth chip pads, respectively; and
sixth conductive wires electrically connecting the plurality of substrate pads and the fourth sub-chip pads.

16. The semiconductor package of claim 15, wherein the third and fourth chip pads and the fourth sub-chip pads are configured to receive a power signal or a ground signal from the package substrate through the fourth to sixth conductive wires.

17. A semiconductor package, comprising:
a package substrate having a plurality of substrate pads;
a first semiconductor chip stacked on the package substrate, the first semiconductor chip including a plurality of first chip pads, a plurality of first sub-chip pads, and a plurality of first wirings, the first chip pads along a first horizontal direction, the first sub-chip pads along a second horizontal direction perpendicular to the first horizontal direction, the first wirings electrically connecting the first chip pads and the first sub-chip pads to each other;
a second semiconductor chip stacked on the first semiconductor chip to cover the first sub-chip pads, the second semiconductor chip including a plurality of second chip pads, a plurality of second sub-chip pads, and a plurality of second wirings, the second chip pads along the first horizontal direction, the second sub-chip pads along the second horizontal direction, the second wirings electrically connecting the second chip pads and the second sub-chip pads to each other; and
a plurality of connection lines electrically connecting the first and second chip pads and the second sub-chip pads to the substrate pads and configured to transmit a power signal or a ground signal.

18. The semiconductor package of claim 17, wherein the plurality of connection lines include:
first conductive wires electrically connecting the plurality of substrate pads and the first chip pads;
second conductive wires electrically connecting the first chip pads and the second chip pads; and
third conductive wires electrically connecting the plurality of substrate pads and the second sub-chip pads.

19. The semiconductor package of claim 17, wherein the first sub-chip pads receive the power signal or the ground signal from the first chip pads through the first wirings.

20.-26. (canceled)

27. A semiconductor package, comprising:
a package substrate having a plurality of substrate pads;
a first semi-package having first and second semiconductor chips sequentially stacked on the package substrate;
a second semi-package having third and fourth semiconductor chips sequentially stacked on the first semi-package; and
a plurality of connection lines electrically connecting the first and second semi-packages to the package substrate and configured to transmit a power signal or a ground signal,
wherein the first semiconductor chip includes,
a plurality of first chip pads along a first horizontal direction,
a plurality of first sub-chip pads along a second horizontal direction perpendicular to the first horizontal direction, and
a plurality of first wirings electrically connecting the first chip pads and the first sub-chip pads to each other,
wherein the second semiconductor chip includes,
a plurality of second chip pads along the first horizontal direction,
a plurality of second sub-chip pads along the second horizontal direction, and
a plurality of second wirings electrically connecting the second chip pads and the second sub-chip pads to each other,
wherein the second semiconductor chip is stacked on the first semiconductor chip to cover the first sub-chip pads and expose the first chip pads,
wherein the third semiconductor chip includes,
a plurality of third chip pads along the first horizontal direction;
a plurality of third sub-chip pads along the second horizontal direction; and
a plurality of third wirings electrically connecting the third chip pads and the third sub-chip pads to each other,
wherein the third semiconductor chip is stacked on the second semiconductor chip to expose the second chip pads and the second sub-chip pads,
wherein the fourth semiconductor chip includes,
a plurality of fourth chip pads along the first horizontal direction,
a plurality of fourth sub-chip pads along the second horizontal direction, and
a plurality of fourth wirings electrically connecting the fourth chip pads and the fourth sub-chip pads to each other, and
wherein the fourth semiconductor chip is stacked on the third semiconductor chip to cover the third sub-chip pads and expose the third chip pads.

28.-30. (canceled)
